(19) United States
(12) Patent Application Publication
(10) Pub. No.: US 2025/0294852 A1
(43) Pub. Date: Sep. 18, 2025

(54) SEMICONDUCTOR DEVICE

(71) Applicant: Dynax Semiconductor, Inc., Suzhou (CN)

(72) Inventors: Hongtu QIAN, Suzhou (CN); Zili WU, Suzhou (CN); Xiao HAN, Suzhou (CN)

(73) Assignee: Dynax Semiconductor, Inc., Suzhou (CN)

(21) Appl. No.: 19/223,349

(22) Filed: May 30, 2025

Related U.S. Application Data
(63) Continuation of application No. PCT/CN2023/143560, filed on Dec. 29, 2023.

(30) Foreign Application Priority Data
Dec. 30, 2022 (CN) 202211736871.0
Dec. 30, 2022 (CN) 202211740351.7
Dec. 30, 2022 (CN) 202211740915.7

(51) Int. Cl. H10D 64/27; H10D 30/47; H10D 62/85

(52) U.S. Cl. CPC H10D 64/518; H10D 30/475; H10D 62/8503

(57) ABSTRACT

A semiconductor device includes: a substrate; an epitaxial structure located on a side of the substrate; a gate electrode located on the side, facing away from the substrate, of the epitaxial structure. The gate electrode extends in a first direction parallel to a plane of the substrate and the gate electrode is in Schottky contact with the epitaxial structure; a gate connecting structure comprising a first gate connecting section and a second gate connecting section connected with each other, wherein the second gate connection section is electrically connected to at least part of the gate electrode. According to the semiconductor device, by providing a gate connecting structure, effect of resistance of a gate may be reduced, thereby increasing switching speed and improving a gain.

### CROSS-REFERENCE TO RELATED APPLICATIONS

This application is a continuation of International Application No. PCT/CN2023/143560, filed on Dec. 29, 2023, which claims priority to Chinese Patent Application No. 202211740351.7, filed on Dec. 30, 2022, Chinese Patent Application No. 202211740915.7, filed on Dec. 30, 2022, and Chinese Patent Application No. 202211736871.0, filed on Dec. 30, 2022. The disclosures of the aforementioned applications are hereby incorporated by reference in their entireties.

### TECHNICAL FIELD

The present disclosure relates to the field of semiconductor technologies, and in particular, to a semiconductor device.

### BACKGROUND

Gallium Nitride (GaN), as a semiconductor material, has become a research hot spot due to characteristics such as wide band gap, high electron saturation drift velocity, high breakdown field strength, and good thermal conductivity.

As for a GaN radio frequency (RF) power amplifier, it is required for an application circuit to achieve a balance between improvement in device power and gain characteristics, which is also a goal pursued by GaN RF chips. However, since power supply of a gate electrode is located on a single side of a device, the power supply for a gate on the other side is affected by resistance of the gate electrode, resulting in performance degradation.

### SUMMARY

The present disclosure provides a semiconductor device to reduce influence of resistance of a gate electrode, thereby increasing a gain and switching speed of the device.

In a first aspect, the present disclosure provides a semiconductor device, including: a substrate; an epitaxial structure located on a side of the substrate; a gate electrode located on a side, facing away from the substrate, of the epitaxial structure, where the gate electrode extends in a first direction parallel to a plane of the substrate, the gate electrode includes a first gate section and a second gate section connected with each other and the gate electrode is in Schottky contact with the epitaxial structure; and a gate connecting structure including a first gate connecting section and a second gate connecting section connected with each other, where the second gate connection section is electrically connected to at least part of the gate electrode.

According to the semiconductor device provided by the embodiments of the present disclosure, resistance of the gate electrode is reduced by providing a gate connecting structure that is electrically connected to at least part of the gate electrode, thereby improving a gate gain and switching speed of the device.

### BRIEF DESCRIPTION OF THE DRAWINGS

To more clearly illustrate technical solutions in embodiments of the present disclosure, accompanying drawings used in the description of the embodiments will be briefly introduced below. Obviously, the accompanying drawings in the following description are merely some embodiments of the present disclosure. For those skilled in the art, other accompanying drawings may be obtained from these accompanying drawings without creative effort.

FIG. 1 is a schematic structural diagram of a semiconductor device provided by an embodiment of the present disclosure.

FIG. 2 is a schematic structural diagram of a semiconductor device provided by another embodiment of the present disclosure.

FIG. 3 is a cross-sectional view of the semiconductor device shown in FIG. 1 or FIG. 2 along section line A-A′.

FIG. 4 is a cross-sectional view of the semiconductor device shown in FIG. 2 along section line B-B′.

FIG. 5 is a schematic structural diagram of a semiconductor device provided by another embodiment of the present disclosure.

FIG. 6 is a schematic structural diagram of a semiconductor device provided by still another embodiment of the present disclosure.

FIG. 7 is a schematic structural diagram of a semiconductor device provided by yet still another embodiment of the present disclosure.

FIG. 8 is a schematic structural diagram of a semiconductor device provided by yet still another embodiment of the present disclosure.

FIG. 9 is a schematic structural diagram of a semiconductor device provided by yet still another embodiment of the present disclosure.

FIG. 10 is a schematic structural diagram of a semiconductor device provided by yet still another embodiment of the present disclosure.

FIG. 11 is a cross-sectional view of the semiconductor device shown in FIG. 10 along section line A-A′.

FIG. 12 is a cross-sectional view of the semiconductor device shown in FIG. 10 along section line B-B′.

FIG. 13 is a schematic structural diagram of a semiconductor device provided by yet still another embodiment of the present disclosure.

FIG. 14 is a schematic structural diagram of a semiconductor device provided by yet still another embodiment of the present disclosure.

FIG. 15 is a cross-sectional view of the semiconductor device shown in FIG. 14 along section line F-F′.

FIG. 16 is a cross-sectional view of the semiconductor device shown in FIG. 14 along section line E-E′.

### DETAILED DESCRIPTION OF THE EMBODIMENTS

Technical solutions in embodiments of the present disclosure will be described clearly and completely with reference to the accompanying drawings in the following. Obviously, the described embodiments are only part of the embodiments of the present disclosure, rather than all of them. Based on the embodiments of the present disclosure, all other embodiments obtained by those skilled in the art without creative effort shall fall within the scope of protection of the present disclosure.

In the description of the embodiments of the present disclosure, it should be understood that the terms “first” and “second” are used for descriptive purposes only and should not be construed as indicating or implying relative importance or implicitly specifying the quantity of the indicated technical features. Thus, features defined as “first” or “second” may explicitly or implicitly include one or more of the said features. In the description of the embodiments of the present disclosure, “a plurality” means two or more, unless otherwise specifically defined.

To enable those skilled in the art to implement and use the present disclosure, the following description is provided. Details are listed in the following description for explanatory purposes. It should be understood that those skilled in the art can recognize that the present disclosure can be implemented without these specific details. In other embodiments, well-known processes are not described in detail to avoid obscuring the description of the embodiments of the present disclosure with unnecessary details. Therefore, the present disclosure is not intended to be limited to the illustrated embodiments but is to be accorded the widest scope consistent with the principles and features disclosed in the embodiments of the present disclosure.

Gallium Nitride (GaN) semiconductor materials have become a research hot spot due to their characteristics such as wide band gap, high electron saturation drift velocity, high breakdown field strength, and good thermal conductivity. In terms of an electronic device, GaN materials are more suitable than silicon and gallium arsenide for manufacturing high-temperature, high-frequency, high-voltage, and high-power devices, offering broad application prospects.

In the field of 5G communication, semiconductor RF devices require high bandwidth and high-frequency performance. Design and processing procedures of a gate structure are closely related to the frequency characteristics of the semiconductor device, directly affecting their operating frequency. Therefore, the design of the gate structure is particularly important in the design and preparation of the semiconductor device, playing a key role in the reliability and operational stability of the semiconductor device.

As for a GaN radio frequency (RF) power amplifiers, it is required for an application circuit to achieve a balance between improvement in device power and gain characteristics, which is also a goal pursued by GaN RF chips. Specifically, in a design of a traditional integrated circuit GaN RF chip, power supply of a gate electrode is located on a single side of a device, so that the power supply for a gate on the other side is reduced under an effect of the gate electrode, resulting in significant reduction in gain. Therefore, how to improve the gain of the semiconductor device while further enhancing their bandwidth and high-frequency performance, thereby achieving a performance balance in power amplifiers, has become an urgent problem to solve.

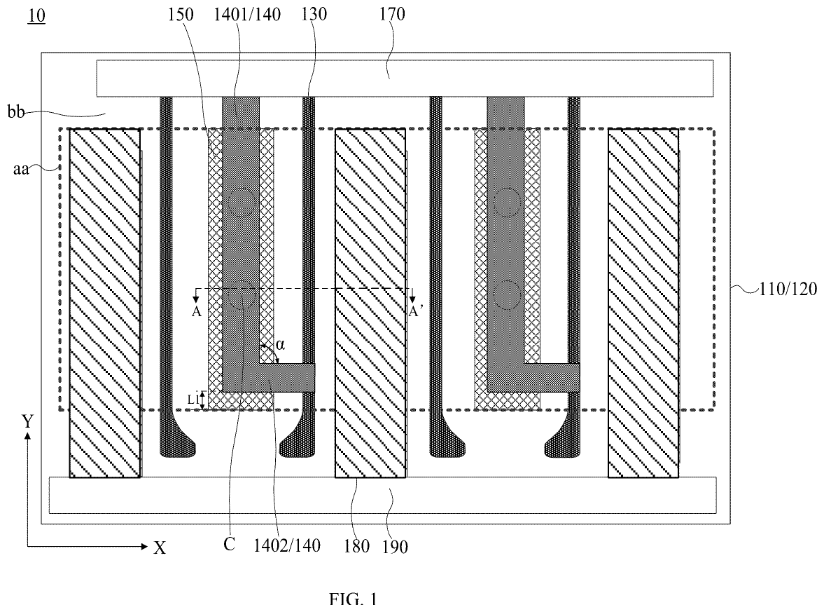

The present disclosure provides a semiconductor device. The semiconductor device includes a substrate, an epitaxial structure, a gate electrode, and a gate connecting structure. The epitaxial structure is located on a side of the substrate. The gate electrode is located on a side, facing away from the substrate, of the epitaxial structure. The gate electrode extends in a first direction (e.g., a Y direction shown in FIG. 1), where the first direction Y is parallel to a plane of the substrate. The gate electrode includes a first gate section and a second gate section connected with each other, and the gate electrode is in a Schottky contact with the epitaxial structure. The gate connecting structure includes a first gate connecting section and a second gate connecting section connected with each other. The second gate connecting section is electrically connected to at least part of the gate electrode. By providing the gate connecting structure that is electrically connected to at least part of the gate electrode, resistance of the gate electrode may be reduced, thereby improving a gate gain and switching speed of the device.

Exemplarily, the substrate of the semiconductor device may be made of at least one of silicon, sapphire, silicon carbide, or gallium arsenide. The epitaxial structure may be made of Group III-V nitrides including one or more of gallium nitride, aluminum gallium nitride, indium gallium nitride, aluminum nitride, and indium aluminum gallium nitride. The gate connecting structure may be made of conductive metal, such as a low-resistance conductive material, to reduce resistance of the gate electrode.

In some embodiments, the semiconductor device includes an active region and a passive region surrounding the active region. The active region can be understood as a region where a two-dimensional electron gas (2DEG), electrons, or holes exist below. An operating state and characteristics of the active region are influenced by external circuits, making it an active working region of the semiconductor device. The passive region participates in the operation of the semiconductor device, but its operating state is not affected by the external circuits. Exemplarily, lead-out structures for electrodes in the active region may be provided in the passive region, and the passive region may be arranged to surround the active region.

The gate connecting structure may be electrically connected to at least part of the gate electrode in the active region or the passive region. If the gate connecting structure is electrically connected to at least part of the gate electrode in the active region, the semiconductor device can maintain a compact structure, facilitating miniaturized design. If the gate connecting structure is electrically connected to at least part of the gate electrode in the passive region, it can enhance design flexibility of the connection between the gate connecting structure and the gate electrode while avoiding interference with arrangement of the semiconductor device in the active region, ensuring stability of the semiconductor device in the active region. Therefore, those skilled in the art can choose to implement the electrical connection between the gate connecting structure and at least part of the gate electrode in the active region or the passive region based on actual needs.

The following embodiments provide detailed descriptions of the semiconductor device of the present disclosure.

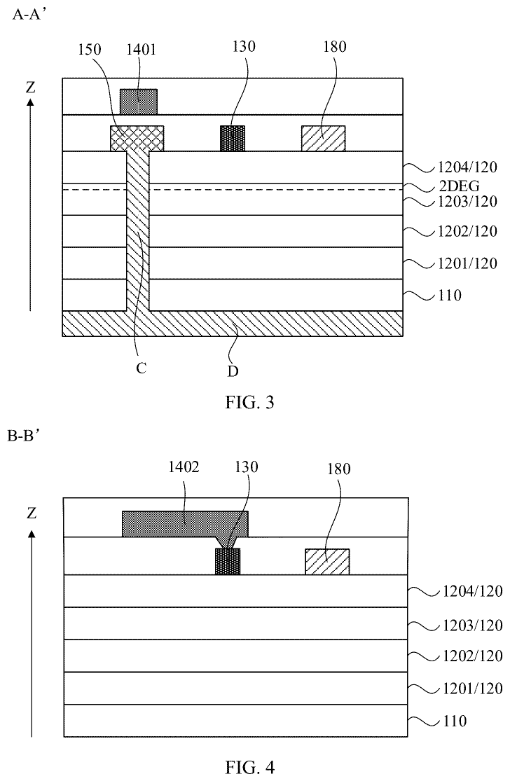

FIG. 1 is a schematic structural diagram of a semiconductor device provided by an embodiment of the present disclosure. FIG. 3 is a cross-sectional view of the semiconductor device shown in FIG. 1 along section line A-A′. As shown in FIGS. 1 and 3, the semiconductor device 10 includes an active region aa. The semiconductor device further includes: a substrate 110; an epitaxial structure 120 located on a side of the substrate 110; a gate electrode 130 located on a side, facing away from the substrate 110, of the epitaxial structure 120, where the gate electrode 130 extends in a first direction (e.g., a direction of Y shown in FIG. 1), the first direction Y is parallel to a plane of the substrate 110, the gate electrode includes a first gate section and a second gate section connected with each other, and the gate electrode 130 is in a Schottky contact with the epitaxial structure 120; and at least one gate connecting structure 140, including a first gate connecting section 1401 and at least one second gate connecting section 1402 connected with each other. In a thickness direction of the semiconductor device 10 (e.g., a direction of Z shown in FIG. 3), an orthographic projection of the gate electrode 130 does not overlap with an orthographic projection of the first gate connecting section 1401, and at least part of the gate electrode 130 is electrically connected to the second gate connecting section 1402 in the active region aa. Exemplarily, the first gate section is located in the active region aa, and the second gate connecting section 1402 is located in the active region aa. At least part of the first gate section is electrically connected to the second gate connecting section 1402 in the active region aa.

FIG. 1 illustrates the semiconductor device 10 including a plurality of gate electrodes. The semiconductor device 10 may also include only one gate electrode 130. That is, a single-cell structure consists of a source electrode 150, a gate electrode 130, and a drain electrode 180.

The gate electrode 130 forms a good Schottky contact with the epitaxial structure 120, serving as a gate structure of the semiconductor device 10 to control turning-on and turning-off of the gate electrode 130, thereby controlling an operating state of the semiconductor device 10. Since charging and discharging speed of a junction capacitance is affected by resistance of the gate electrode, switching speed of the semiconductor device 10 may be further affected. That is, the lower the resistance of the gate electrode is, the faster the switching speed of the semiconductor device 10 is. In the embodiment of the present disclosure, the first gate connecting section 1401 is located in the active region aa and has a relatively large area, serving as a main adjustment structure for gate gain, which may optimize an electric field of the gate electrode 130, reduce resistance of the gate electrode 130, and improve a gate gain and switching speed of the gate electrode 130. The second gate connecting section 1402 is located in the active region aa, serving as a connection portion between the gate electrode 130 and the gate connecting structure 140, ensuring normal connection between the gate electrode 130 and the gate connecting structure 140, reducing the resistance of the gate electrode 130, and facilitating miniaturized design of the semiconductor device.

The gate electrode 130 forms a Schottky contact with the epitaxial structure 120, while the gate connecting structure 140 does not form a Schottky contact with the epitaxial structure 120. Specifically, the gate connecting structure 140 is not in direct contact with a conductive channel (e.g., 2DEG) in the epitaxial structure 120.

In the thickness direction Z of the semiconductor device 10, the orthographic projection of the gate electrode 130 does not overlap with the orthographic projection of the first gate connecting section 1401. In other words, in a second direction (e.g., a direction of X shown in FIG. 1), the first gate section is spaced from the first gate connecting section 1401, that is, the first gate section is offset from the first gate connecting section 1401.

Exemplarily, further referring to FIG. 1, the gate connecting structure 140 at least includes the second gate connecting section 1402 located at an edge of the active region aa, and at least part of the gate electrode 130 is electrically connected to the second gate connecting section 1402 at the edge of the active region aa.

Optionally, a minimum distance between the second gate connecting section 1402 and the edge of the active region aa is L1, where L1≤5 μm. Specifically, the minimum distance L1 between the second gate connecting section 1402 and the edge of the active region aa can be understood as a distance from the second gate connecting section 1402 to a boundary of the active region aa in the first direction Y. By setting the minimum distance L1 to a small value, it may be avoided to interference with the normal arrangement and performance of the semiconductor device 10 in the active region aa, ensuring proper operation of the semiconductor device 10 and meeting requirements for the preparation process.

Optionally, further referring to FIG. 1, in the second direction X, a dimension of the first gate connecting section 1401 is greater than a dimension of the gate electrode 130. The second direction X and the first direction Y intersect and are parallel to the plane of the substrate 110. Specifically, the dimension of the first gate connecting section 1401 being greater than that of the gate electrode 130 in the second direction X means that a width of the first gate connecting section 1401 in the second direction X is greater than a width of the gate electrode 130 in the second direction X. Since the first gate connecting section 1401 has a larger dimension, its resistance is lower. By electrically connecting the gate connecting structure 140 to the gate electrode 130, the electric field of the gate electrode 130 may be optimized, thereby reducing resistance of the gate electrode 130, and improving a gain of the semiconductor device 10.

Exemplarily, in the second direction X, the dimension of the first gate connecting section 1401 may be 2 times, 3 times, or 3.2 times the dimension of the gate electrode 130, which is not limited in present disclosure as long as the dimension of the first gate connecting section 1401 is greater than the dimension of the gate electrode 130 to reduce resistance of the gate electrode 130. Further, while meeting requirements for a size of the semiconductor device 10 and the design of the active region aa, the dimension of the first gate connecting section 1401 in the second direction X may be designed as large as possible to minimize the resistance of the gate electrode 130, optimize the electric field of the gate electrode 130, and improve the switching speed and gain of the semiconductor device 10.

Optionally, further referring to FIG. 1, a dimension of the second gate connecting section 1402 in the first direction Y is greater than a dimension of the gate electrode 130 within the active region aa in the second direction X. The second direction X and the first direction Y intersect and are parallel to the plane of the substrate 110. Specifically, the dimension of the second gate connecting section 1402 in the first direction Y being greater than the dimension of the gate electrode 130 in the second direction X may ensure sufficient electrical connection between the second gate connecting section 1402 and the gate electrode 130, reducing the resistance of the gate connecting structure 140 and enabling rapid current transmission to the first gate connecting section 1401, thereby improving the switching speed and gain of the semiconductor device 10.

In some embodiments, further referring to FIG. 1, a dimension of at least part of the gate electrode 130 in the passive region bb in the second direction X is greater than the dimension of the gate electrode 130 in the active region aa in the second direction X. Exemplarily, the gate region, farther away from the active region aa, resistance of the gate electrode 130 in the passive region bb has a larger size in the second direction X than in the active region aa, further optimizing the electric field between the gate electrode 130 and a source electrode 150. Additionally, a curvature radius of the gate electrode 130 in the passive region bb in the second direction X may be greater than a width of the gate electrode 130 in the active region aa in the second direction X, reducing difficulty of penetration of developer solution from an end of the gate electrode 130 toward a center of the gate electrode 130 and reducing development difficulty. Moreover, the gate electrode 130 at corners of the source and drain may be moderately compensated to mitigate or eliminate reduction in gate width caused by light diffraction.

Optionally, further referring to FIG. 1, an angle between the second gate connecting section 1402 and the first gate connecting section 1401 is a, where 80°≤a≤100°. Specifically, an arrangement space of the active region aa is determined by a size of the angle α. When the angle α is approximately perpendicular, a space occupied by the second gate connecting section 1402 in the first direction Y within the active region aa may be reduced, facilitating the miniaturized design of the semiconductor device 10. Exemplarily, the angle α may be 80°, 90°, or 100°.

Optionally, further referring to FIG. 1, the first gate connecting section 1401 and the second gate connecting section 1402 are arranged in the same layer, simplifying film structure of the semiconductor device 10 and facilitating thinner design of the semiconductor device 10. Additionally, the first gate connecting section 1401 and the second gate connecting section 1402 may be integrally formed in the same process, simplifying preparation process of the semiconductor device 10, reducing fabrication difficulty, and improving production efficiency.

Optionally, further referring to FIGS. 1 and 3, the semiconductor device 10 may further include a source electrode 150 in an ohmic contact with the epitaxial structure 120. In the thickness direction Z of the semiconductor device 10, the orthographic projection of the first gate connecting section 1401 overlaps with an orthographic projection of the source electrode 150 and the first gate connecting section 1401 is insulated from it the source electrode 150. Exemplarily, the first gate connecting section 1401 may be located above the source electrode 150, so that the orthographic projection of the first gate connecting section 1401 overlaps with the orthographic projection of the source electrode 150. On one hand, this arrangement does not affect signal leading out of the gate electrode 130; on the other hand, an area of the semiconductor device 10 may be reduced by the overlap between the orthographic projection of the first gate connecting section 1401 and the orthographic projection of the source electrode 150.

Further referring to FIGS. 1 and 3, the source electrode 150 may be connected to a backside of the semiconductor device 10 through a source via hole C. Exemplarily, the source via hole C may penetrate the substrate 110 and the epitaxial structure 120, connecting to a source signal input electrode D on a side, facing away from the epitaxial structure 120, of the substrate 110. In other words, the source electrode 150 is electrically connected to the source signal input electrode D through the source via hole C. Further, the first gate connecting section 1401 may be located above the source via hole C, ensuring stability of the source via hole C region and the proper operation of the semiconductor device 10.

Optionally, further referring to FIG. 1, a dimension of the first gate connecting section 1401 in the second direction X is smaller than a dimension of the source electrode 150 in the second direction X. The second direction X and the first direction Y intersect and are parallel to the plane of the substrate 110. Specifically, a smaller size of the first gate connecting section 1401 compared to the source electrode 150 in the second direction X may reduce parasitic capacitance between the gate connecting structure 140 and the source electrode 150, minimizing its influence on the performance of the semiconductor device 10 and ensuring normal operation.

Optionally, further referring to FIG. 1, the semiconductor device 10 may further include a drain electrode 180 and a drain pad 190 connected with each other. The drain electrode 180 forms an ohmic contact with the epitaxial structure 120. In the first direction Y, the drain pad 190 is located on a second side of the active region aa. In the first direction Y, the second gate connecting section 1402 is located on a side, closer to the drain pad 190, of the active region aa. Exemplarily, the drain electrode 180 in the active region aa may be connected to the drain pad 190 in the passive region bb through drain interconnect metal. Specifically, in the first direction Y, the drain pad 190 is located on the second side of the active region aa (i.e., the side closer to the second gate connecting section 1402), allowing the drain electrode 180 to receive a drain voltage signal through the drain pad 190, ensuring the normal operation of the semiconductor device 10. Further, the second gate connecting section 1402 being located on the side, close to the drain pad 190, of the active region aa may further reduce the area of the active region aa, achieving miniaturized design for the semiconductor device 10.

Optionally, further referring to FIG. 3, the epitaxial structure 120 may include a nucleation layer 1201, a buffer layer 1202, a channel layer 1203, and a barrier layer 1204 stacked in sequence. A heterojunction structure is formed by the channel layer 1203 and the barrier layer 1204.

Exemplarily, the nucleation layer 1201 is located between the substrate 110 and the buffer layer 1202, and a material of the nucleation layer 1201 may be aluminum nitride, serving to bond subsequent semiconductor material layers.

Exemplarily, the buffer layer 1202 is located on a side, facing away from the substrate 110, of the nucleation layer 1201, and a material of the buffer layer 1202 may be gallium nitride, possibly including iron atoms to achieve high resistance of the buffer layer 1202, thereby blocking vertical leakage and improving a pinch-off characteristic of the semiconductor device.

Exemplarily, the channel layer 1203 is located on the side, facing away from the substrate 110, of the buffer layer 1202, and a material of the channel layer 1203 may be a Group III nitride material, such as AlₓGa₁₋ₓN, where 0≤x<1. That is, at an interface between the channel layer 1203 and the barrier layer 1204, energy at an edge of a conduction band of the channel layer 1203 is lower than energy at an edge of a conduction band of the barrier layer 1204. Exemplarily, x=0, which indicates that the material of the channel layer 1203 is GaN. The material of the channel layer 1203 may also be other Group III nitrides, such as InGaN or AlInGaN. The channel layer 1203 may be undoped or unintentionally doped. The channel layer 1203 may be a multilayer structure, such as a superlattice or a combination of GaN and AlGaN.

Exemplarily, the barrier layer 1204 is located on a side, facing away from the substrate 110, of the channel layer 1203 and the material of the barrier layer 1204 may be AlN, AlInN, AlGaN, or AlInGaN. The barrier layer 1204 has a sufficient thickness and high Al composition to form a significant carrier concentration at the interface between the channel layer 1203 and the barrier layer 1204. Exemplarily, the thickness of the barrier layer 1204 may be 20 nm, with an Al composition doping concentration of 25%.

Exemplarily, the channel layer 1203 may include GaN, while the barrier layer 1204 may include AlGaN, that is, the material of the barrier layer 1204 has a wider band gap than the material of the channel layer 1203, and the channel layer 1203 has higher electron affinity than the barrier layer 1204. Due to the band gap difference between the barrier layer 1204 and the channel layer 1203 and piezoelectric effect at the interface between the barrier layer 1204 and the channel layer 1203, a two-dimensional electron gas (2DEG) may be formed at their interface.

Further referring to FIGS. 1 and 3, the epitaxial structure 120 may further include a cap layer located on a surface, facing away from the substrate 110, of the barrier layer 1204. The cap layer may reduce surface states, minimize surface leakage of the semiconductor device, suppress current collapse, and improve the performance and reliability of the epitaxial structure 120 and the semiconductor device 10.

In the embodiments of the present disclosure, by providing at least one gate connecting structure and electrically connecting at least part of the gate electrode to the second gate connecting section in the active region, effect on resistance of the gate electrode may be reduced, thereby improving switching speed and gain. Further, by electrically connecting the gate connecting structure to the gate electrode in the active region rather than the passive region, the semiconductor device may be maintained as a compact structure, facilitating miniaturized design.

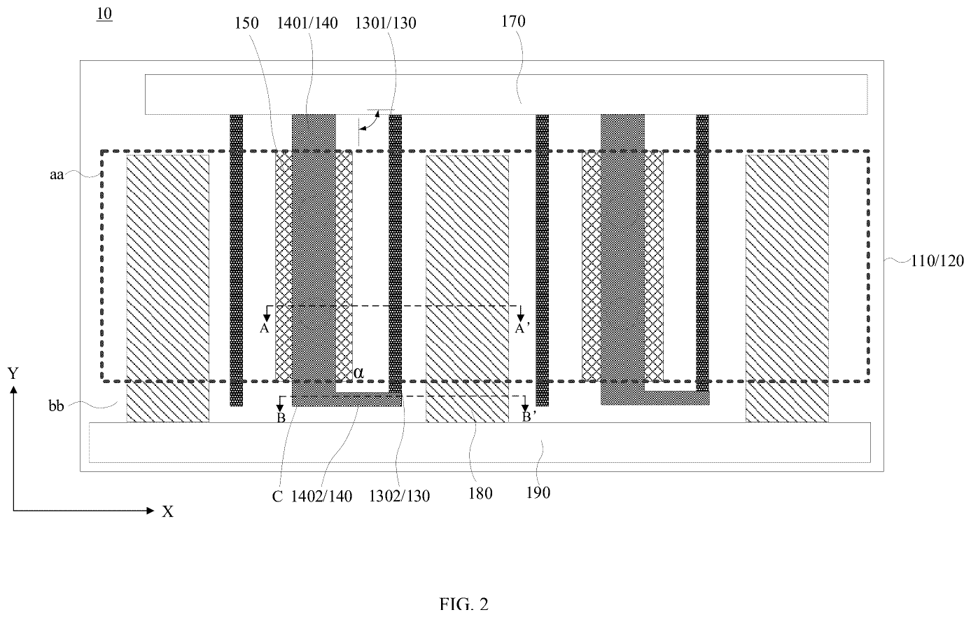

FIG. 2 is a schematic structural diagram of a semiconductor device provided by another embodiment of the present disclosure. FIG. 4 is a cross-sectional view of the semiconductor device shown in FIG. 2 along section line B-B′. Referring to FIGS. 2 to 4, the semiconductor device 10 includes an active region aa and a passive region bb surrounding the active region aa. The semiconductor device 10 further includes: a substrate 110; an epitaxial structure 120 located on a side of the substrate 110; a gate electrode 130 located on a side, facing away from the substrate 110, of the epitaxial structure 120, where the gate electrode 130 extends in a first direction (e.g., the direction of Y shown in FIG. 1), and the first direction Y is parallel to the plane of the substrate 110, the gate electrode 130 includes a first gate section 1301 and a second gate section 1302 connected with each other, the first gate section 1301 forms a Schottky contact with the epitaxial structure 120, and the second gate section 1302 is located in the passive region bb; at least one gate connecting structure 140, including a first gate connecting section 1401 and a second gate connecting section 1402 connected with each other, where the second gate connecting section 1402 is located in the passive region bb. In a thickness direction of the semiconductor device 10 (e.g., a direction of Z shown in FIG. 3), an orthographic projection of the first gate section 1301 does not overlap with an orthographic projection of the first gate connecting section 1401, and at least part of the second gate section 1302 is electrically connected to the second gate connecting section 1402.

FIG. 2 illustrates the semiconductor device 10 including a plurality of gate electrodes. The semiconductor device 10 may also include only one gate electrode 130. That is, a single-cell structure consists of a source electrode 150, a gate electrode 130, and a drain electrode 180.

The gate electrode 130 includes the first gate section 1301 and the second gate section 1302 connected with each other, and the gate connecting structure 140 includes the first gate connecting section 1401 and the second gate connecting section 1402 connected with each other. The first gate section 1301 includes a part located in the active region aa that forms a Schottky contact with the epitaxial structure 120 and another part extending in the first direction Y to connect to a gate pad 170. The first gate section 1301 serves as a gate structure of the semiconductor device 10, controlling turn-on and turn-off of the gate electrode 130 and thus the operating state of the semiconductor device 10. The first gate connecting section 1401 is located in the active region aa and has a relatively large area, serving as a main adjustment structure for gate gain, reducing resistance of the gate electrode 130 and improving a gain of the gate electrode 130. The second gate section 1302 and the second gate connecting section 1402 are both located in the passive region bb and serve as connection portions between the gate electrode 130 and the gate connecting structure 140, ensuring normal connection between the gate electrode 130 and the gate connecting structure 140 and reducing resistance of the gate electrode 130. Further, the electrical connection between the second gate section 1302 and the second gate connecting section 1402 in the passive region bb does not affect an arrangement of the semiconductor device 10 in the active region aa and a normal operation and performance of the active area aa, thereby ensuring the stability of performance of the semiconductor device 10. Moreover, since the passive region bb offers more design space, the second gate section 1302 and the second gate connecting section 1402 can be designed with greater flexibility, enhancing connection stability between the second gate section 1302 and the second gate connecting section 1402.

The gate electrode 130 forms a Schottky contact with the epitaxial structure 120, while the gate connecting structure 140 does not form a Schottky contact with the epitaxial structure 120. Specifically, the gate connecting structure 140 is not in direct contact with a conductive channel (e.g., the 2DEG) in the epitaxial structure 120.

In the thickness direction Z of the semiconductor device 10, the orthographic projection of the first gate section 1301 does not overlap with the orthographic projection of the first gate connecting section 1401, which means that in the second direction (e.g., a direction of X shown in FIG. 2), the first gate section 1301 and the first gate connecting section 1401 do not overlap, that is, the first gate section 1301 is offset from the first gate connecting section 1401.

Optionally, further referring to FIG. 2, in the second direction X, a dimension of the first gate connecting section 1401 is greater than a dimension of the first gate section 1301. The second direction X and the first direction Y intersect and are parallel to the plane of the substrate 110. Specifically, the dimension of the first gate connecting section 1401 being greater than the dimension of the first gate section 1301 in the second direction X means that a width of the first gate connecting section 1401 in the second direction X is greater than a width of the first gate section 1301 in the second direction X. Since the first gate connecting section 1401 has a larger size, its resistance is lower. By electrically connecting the gate connecting structure 140 to the gate electrode 130, resistance of the gate electrode may be effectively reduced, thereby improving a gain of the semiconductor device 10.

Exemplarily, in the second direction X, the dimension of the first gate connecting section 1401 may be 2 times, 3 times, or 3.2 times the dimension of the first gate section 1301, which is not limited by the present disclosure as long as the dimension of the first gate connecting section 1401 is greater than the dimension of the first gate section 1301 to reduce resistance of the gate electrode 130. Further, while meeting requirements for a size of the semiconductor device 10 and the design of the active region aa, the dimension of the first gate connecting section 1401 in the second direction X may be designed as large as possible to minimize the resistance of the gate electrode 130.

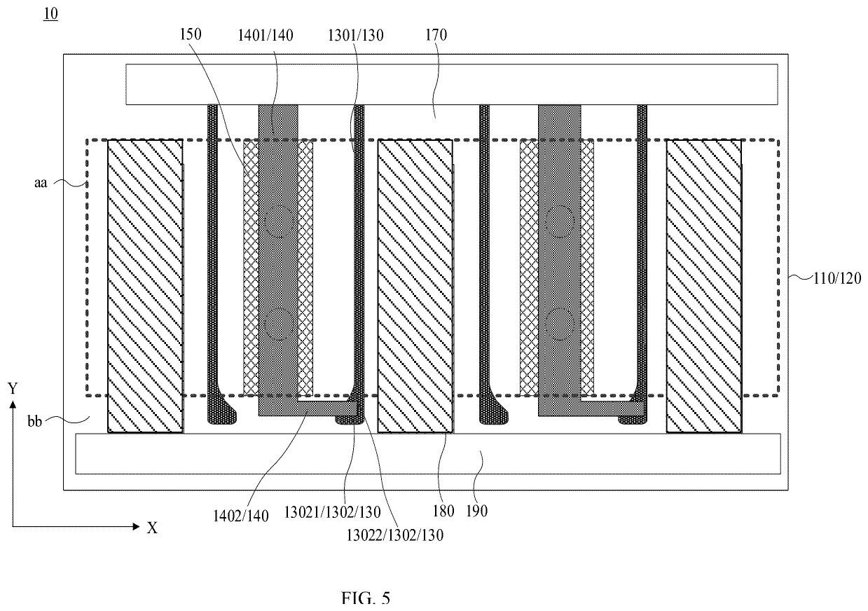

FIG. 5 is a schematic structural diagram of a semiconductor device provided by another embodiment of the present disclosure. A difference between FIG. 5 and FIG. 2 lies in the structure of the second gate section 1302. Referring to FIG. 5, in the first direction Y, a dimension of the second gate section 1302 is greater than a dimension of the second gate connecting section 1402. The second gate section 1302 includes a first sub-portion 13021 and a second sub-portion 13022. The first sub-portion 13021 is located on a side, farther away from the active region aa, of the second sub-portion 13022. In the second direction X, a dimension of the first sub-portion 13021 is greater than a dimension of the second sub-portion 13022. The second direction and the first direction intersect and are parallel to a plane of the substrate.

Specifically, the dimension of the second gate section 1302 being greater than the dimension of the second gate connecting section 1402 may ensure a sufficient contact area between the second gate section 1302 and the second gate connecting section 1402. Further, the second gate section 1302 includes a first sub-portion 13021 and a second sub-portion 13022. The first sub-portion 13021 is located on a side, farther away from the active region aa, of the second sub-portion 13022. In the second direction X, the dimension of the first sub-portion 13021 is greater than the dimension of the second sub-portion 13022. The second gate connecting section 1402 is electrically connected to the first sub-portion 13021, that is, a connection position between the second gate connecting section 1402 and the second gate section 1302 is set in a wider part of the second gate section 1302. Thus, stability of the connection may be improved, making the connection firm and the structure more stable. On the other hand, a connection resistance and connection difficulty between the second gate connecting section 1402 and the second gate section 1302 may be reduced.

Optionally, further referring to FIG. 5, the dimension of the second gate connecting section 1402 in the first direction Y is smaller than a dimension of the first gate connecting section 1401 in the second direction X. The second direction X and the first direction Y intersect and are parallel to the plane of the substrate 110. Specifically, the dimension of the second gate connecting section 1402 in the first direction Y being smaller than the dimension of the first gate connecting section 1401 in the second direction X may reduce a space occupied by the passive region bb, thereby facilitating the miniaturized design of the semiconductor device 10.

Optionally, further referring to FIG. 2, an angle between the second gate connecting section 1402 and the first gate connecting section 1401 is a, where 80°≤a≤100°. Specifically, an arrangement space of the passive region bb is determined by a size of the angle α between the second gate connecting section 1402 and the first gate connecting section 1401. When the angle α is approximately perpendicular, the arrangement space of the passive region bb may be reduced, facilitating the miniaturized design of the semiconductor device 10. Exemplarily, the angle α between the second gate connecting section 1402 and the first gate connecting section 1401 may be 80°, 90°, or 100°.

Optionally, further referring to FIG. 2, the first gate connecting section 1401 and the second gate connecting section 1402 are arranged in the same layer.

Optionally, further referring to FIGS. 2 and 3, the semiconductor device 10 may further include a source electrode 150 in an ohmic contact with the epitaxial structure 120. In the thickness direction Z of the semiconductor device 10, the orthographic projection of the first gate connecting section 1401 overlaps with an orthographic projection of the source electrode 150 and the first gate connecting section 1401 is insulated from the source electrode 150. The source electrode 150 may be connected to a backside of the semiconductor device 10 through a source via hole C. Exemplarily, the source via hole C may penetrate the substrate 110 and the epitaxial structure 120, connecting to a source signal input electrode D on a side, facing away from the epitaxial structure 120, of the substrate 110. In other words, the source electrode 150 is electrically connected to the source signal input electrode D through the source via hole C. Optionally, further referring to FIG. 2, a dimension of the first gate connecting section 1401 in the second direction X is smaller than a dimension of the source electrode 150 in the second direction X. The second direction X and the first direction Y intersect and are parallel to the plane of the substrate 110.

Optionally, further referring to FIG. 2, the semiconductor device 10 may further include a drain electrode 180 and a drain pad 190 connected with each other. The drain electrode 180 forms an ohmic contact with the epitaxial structure 120. In the first direction Y, the drain pad 190 is located on a second side of the active region aa. In the first direction Y, the second gate connecting section 1402 is located on a side, closer to the drain pad 190, of the active region aa. Exemplarily, the drain electrode 180 in the active region aa may be connected to the drain pad 190 in the passive region bb through drain interconnect metal. Specifically, in the first direction Y, the drain pad 190 is located on the second side of the active region aa, that is, the drain electrode 180 may receive a drain voltage signal through the drain pad 190, thereby ensuring the normal operation of the semiconductor device 10. Further, in the first direction Y, the second gate connecting section 1402 is located between the active region aa and the drain pad 190, which reduces an area of the passive region bb, further reducing an area of the semiconductor device 10, thereby achieving miniaturized design for the device.

Optionally, further referring to FIG. 3, the epitaxial structure 120 may include a nucleation layer 1201, a buffer layer 1202, a channel layer 1203, and a barrier layer 1204 stacked in sequence. A heterojunction structure is formed by the channel layer 1203 and the barrier layer 1204. More description of the epitaxial structure 120 may be referred to FIG. 1, which will not be repeated in this embodiment.

In view of above, the semiconductor device provided by the embodiments of the present disclosure incorporates at least one gate connecting structure, which is electrically connected to at least part of the gate electrode, to reduce resistance of the gate electrode, improve gate gain, and minimize leakage. Further, by electrically connecting the gate connecting structure to the gate electrode in the passive region, on one hand, the design flexibility of the connection between the gate connecting structure and the gate electrode is enhanced, and on the other hand, interference with the arrangement of the semiconductor device in the active region may be avoided, ensuring the stability of the semiconductor device in the active region.

In some embodiments, the gate connecting structure 140 is electrically connected to the gate electrode 130 located on a side of the first gate connecting section 1401 in the second direction X through the second gate connecting section 1402. As shown in FIGS. 1 and 2, a shape of the gate connecting structure 140 may resemble an “L,” ensuring a simple arrangement of the gate connecting structure 140 while reducing resistance of the gate electrode 130 and optimizing the electric field of the gate electrode 130 by electrically connecting the gate connecting structure 140 to the gate electrode 130 located on a side of the gate connecting structure 140.

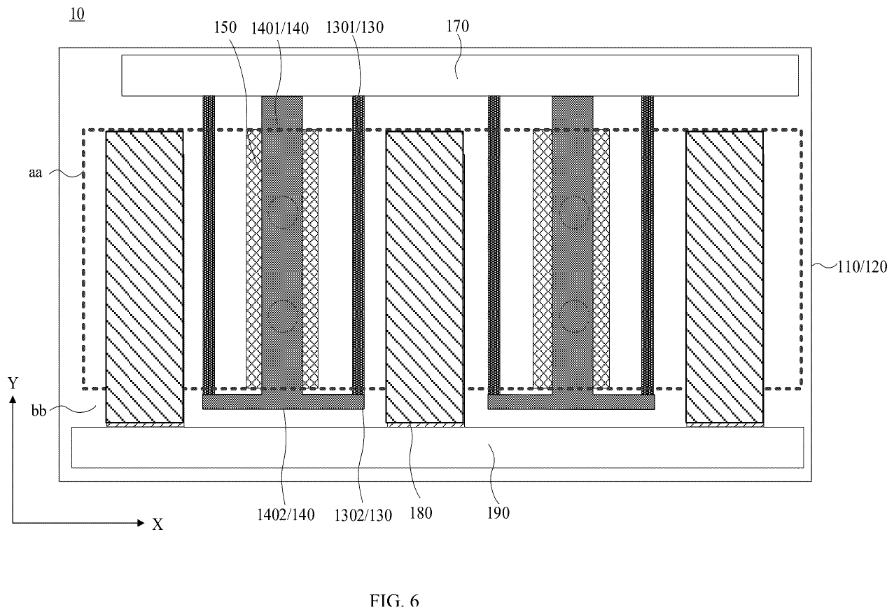

In some embodiments, the semiconductor device may include a plurality of gate electrodes 130 arranged in sequence in the second direction X. The gate connecting structure 140 is electrically connected to two gate electrodes 130 on both sides of the first gate connecting section 1401 in the second direction X through the second gate connecting section 1402. The second direction X and the first direction Y intersect and are parallel to the plane of the substrate 110. As shown in FIG. 6, FIG. 6 is a schematic structural diagram of a semiconductor device provided by still another embodiment of the present disclosure. As shown in FIG. 6, the second gate connecting section 1402 is electrically connected to the gate electrode 130 in the passive region. As shown in FIG. 6, the gate connecting structure 140 is electrically connected to two gate electrodes 130 on both sides of the first gate connecting section 1401 in the second direction X through the second gate connecting section 1402, resembling a “T” shape. That is, one gate connecting structure 140 is electrically connected to the gate electrodes 130 located on both sides. On one hand, a quantity of gate electrodes 130 connected to the gate connecting structure 140 may be increased, effectively reducing resistance of the gate electrode 130 and leakage of the gate electrode 130. On the other hand, a simple arrangement of the gate connecting structure 140 may be ensured, so that interference with other components in the active region aa of the semiconductor device 10 may be minimized, while simplifying the preparation process of the gate connecting structure 140. It should be understood that FIG. 6 only illustrates a case where the second gate connecting section 1402 is electrically connected to the gate electrode 130 in the passive region, but the same applies when the second gate connecting section 1402 is electrically connected to the gate electrode 130 in the active region.

As another feasible implementation, the shape of the gate connecting structure 140 may resemble an “L”, where two gate connecting structures 140 are arranged in a “back-to-back” configuration, ensuring that all gates 130 are electrically connected to the gate connecting structure 140, further reducing resistance of the gate electrode and leakage.

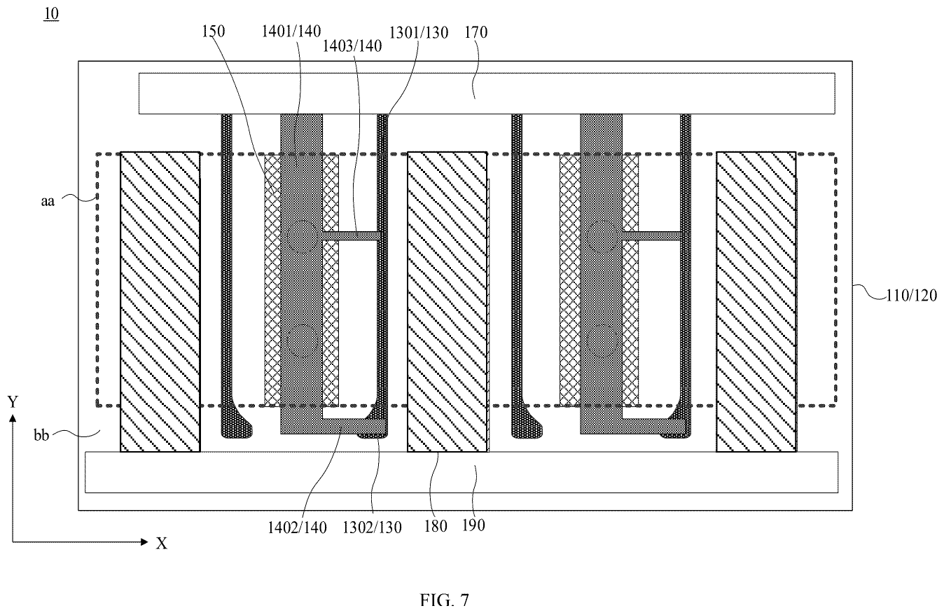

FIG. 7 is a schematic structural diagram of a semiconductor device provided by yet still another embodiment of the present disclosure. As shown in FIG. 7, the gate connecting structure 140 further includes a third gate connecting section 1403, which is located in the active region aa and electrically connected to the first gate connecting section 1401 and the first gate section 1301. Specifically, the third gate connecting section 1403 is located in the active region aa. By electrical connecting the third gate connecting section 1403 to the first gate connecting section 1401 and the first gate section 1301, stability of the connection between the gate connecting structure 140 and the gate electrode 130 may be enhanced while reducing connection resistance. Optionally, if the gate connecting structure 140 includes only one third gate connecting section 1403, the third gate connecting section 1403 is located on a side, farther away from the drain pad 190, of the second gate connecting section 1402. Optionally, if the gate connecting structure 140 includes a plurality of third gate connecting sections 1403, the plurality of third gate connecting sections 1403 are uniformly distributed in the active region aa, with at least one located on the side, farther away from the drain pad 190, of the second gate connecting section 1402. It should be understood that FIG. 7 only illustrates a case where the second gate connecting section 1402 is electrically connected to the gate electrode 130 in the passive region, but the same applies when the second gate connecting section 1402 is electrically connected to the gate electrode 130 in the active region.

In some embodiments, the gate connecting structure 140 is connected to the gate electrode 130 through at least two channels, creating a parallel connection between the gate connecting structure 140 and the gate electrode 130. Optionally, the gate connecting structure 140 may be connected to the gate electrode 130 through the second gate connecting section 1402 and a gate pad 170 (as shown in FIG. 1 or 2). Optionally, the gate connecting structure 140 may be connected to the gate electrode 130 through at least two second gate connecting sections 1402 (as shown in FIG. 7). Exemplarily, the gate connecting structure 140 may be connected to the gate electrode 130 through the second gate connecting section 1402 and the third gate connecting section 1403, where the second gate connecting section 1402 is located in the active region aa or passive region bb, and the third gate connecting section 1403 is located in the active region aa.

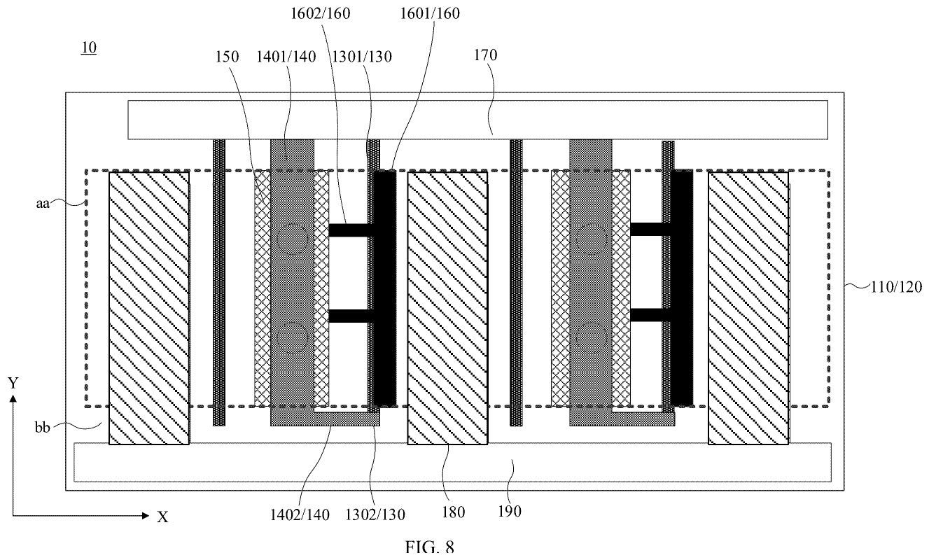

FIG. 8 is a schematic structural diagram of a semiconductor device provided by yet still another embodiment of the present disclosure. As shown in FIG. 8, on the basis of FIG. 7, the semiconductor device 10 may further include a source electrode 150 and a source field plate 160. The source field plate 160 includes a field plate main body 1601 and a field plate branch 1602. One end of the field plate branch 1602 is electrically connected to the field plate main body 1601, and the other end of the field plate branch 1602 is electrically connected to the source electrode 150, enabling an electrical connection between the source field plate 160 and the source electrode 150. The field plate branch 1602 is arranged to be staggered with the third gate connecting section 1403, that is, an orthographic projection of the field plate branch 1602 on the substrate 110 does not overlap with an orthographic projection of the third gate connecting section 1403 on the substrate 110, which prevents interference between the field plate branch 1602 and the third gate connecting section 1403. It should be noted that FIG. 8 only illustrates a case where the second gate connecting section 1402 is electrically connected to the gate electrode 130 in the passive region. The same applies when the second gate connecting section 1402 is electrically connected to the gate electrode 130 in the active region.

Optionally, further referring to FIG. 8, the orthographic projection of the field plate main body 1601 on the substrate 110 may partially overlap with an orthographic projection of the gate electrode 130 on the substrate 110. For example, the orthographic projection of the field plate main body 1601 on the substrate 110 may overlap with a side, closer to the drain electrode 180, of the orthographic projection of the gate electrode 130 on the substrate 110. Thus, the source field plate 160 extends toward the gate electrode 130, further enhancing a modulation effect on the electric field of the source field plate 160. By reducing electric field accumulation of at drain-side edge of the gate electrode 130, a risk of breakdown at this edge of the gate electrode 130 is lowered, thereby improving the reliability of the semiconductor device 10.

Exemplarily, in the thickness direction of the semiconductor device 10, the orthographic projection of the source field plate 160 covers an edge, farther away from the source electrode 150, of the orthographic projection of the gate electrode 130, with an overlap area S1 between the orthographic projection of the source field plate 160 and the orthographic projection of the gate electrode 130. An area of the gate electrode 130 is S2, and a ratio of S1 to S2 is less than or equal to 20%. In other words, the field plate main body 1601 overlaps with the gate electrode 130 to a limited extent.

Optionally, in the thickness direction of the semiconductor device 10, the orthographic projection of the source field plate 160 is staggered with the orthographic projection of the gate electrode 130, which reduces electric field accumulation at the drain-side edge of the gate electrode 130, thereby lowering a risk of breakdown and improving the reliability of the device.

Optionally, further referring to FIG. 8, the semiconductor device 10 may further include a gate pad 170. In the first direction Y, the gate pad 170 is located in the passive region bb at a first side of the active region aa (i.e., a side farther away from the second gate connecting section 1402 of the active region aa). Both the first gate section 1301 and the first gate connecting section 1401 are electrically connected to the gate pad 170. The semiconductor device 10 may further include a source field plate 160 electrically connected to the source electrode 150. The first gate connecting section 1401 may be arranged in a same layer as the gate electrode 130. Alternatively, the first gate connecting section 1401 may be arranged in a same layer as the source field plate 160. Alternatively, the first gate connecting section 1401 may be arranged in a same layer as the gate pad 170. Exemplarily, in the first direction Y, the gate electrode 130 (or first gate section 1301) in the active region aa may be connected to the gate pad 170 in the passive region bb through gate interconnect metal, so that the gate electrode 130 may receive a gate voltage signal via the gate pad 170, thereby ensuring normal operation of the semiconductor device 10.

Specifically, the first gate connecting section 1401 is arranged in the same layer as the gate electrode 130. Alternatively, the first gate connecting section 1401 may be arranged in a same layer as the source field plate 160. Alternatively, the first gate connecting section 1401 may be arranged in a same layer as the gate pad 170. Thus, a preparation process may be simplified. On one hand, arrangement of unnecessary additional layers may be avoided to reduce masking complexity; on the other hand, it may facilitate a thinner and lighter design for the semiconductor device 10. It should be noted that when the first gate connecting section 1401 is arranged in the same layer as the source field plate 160, the field plate branch 1602 need to be staggered with the second gate connecting section 1402 (or third gate connecting section 1403), so that the field plate branch 1602 may not overlap with the second gate connecting section 1402 (or third gate connecting section 1403), thereby preventing mutual interference.

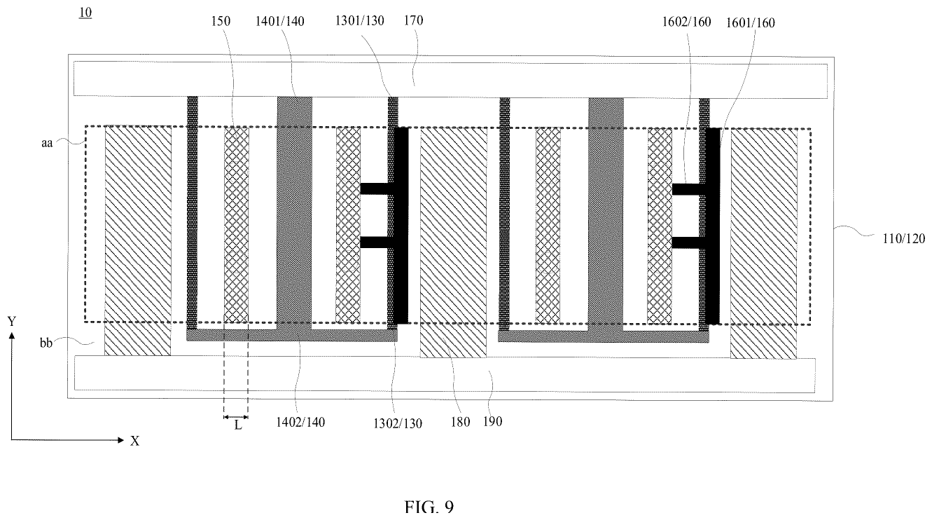

Optionally, FIG. 9 is a schematic structural diagram of a semiconductor device provided by yet still another embodiment of the present disclosure. It should be understood that FIG. 9 only illustrates a case where the second gate connecting section 1402 is electrically connected to the gate electrode 130 in the passive region. The same applies when the second gate connecting section 1402 is electrically connected to the gate electrode 130 in the active region.

As shown in FIG. 9, the second gate connecting section 1402 is electrically connected to the gate electrode 130 in the passive region bb. As shown in FIG. 9, the semiconductor device 10 may further include a source electrode 150, which forms an ohmic contact with the epitaxial structure 120. In the second direction X, the first gate connecting section 1401 is located on a side, farther away from the gate electrode 130, of the source electrode 150 and positioned between two adjacent source electrodes 150. Two adjacent transistor cells share the same first gate connecting section 1401. The second direction X and the first direction Y intersect and are parallel to the plane of the substrate 110. In the second direction X, the first gate connecting section 1401 maintains a certain spacing from the adjacent source electrodes 150, with equal spacing between them.

Specifically, further referring to FIG. 9, in the second direction X, the first gate connecting section 1401 is located on the side, farther away from the gate electrode 130, of the source electrode 150 and between two adjacent source electrodes 150, with two adjacent transistor cells sharing the same first gate connecting section 1401. This arrangement changes a conventional layout where adjacent transistor cells share a single source electrode to a layout where a drain electrode 180, a gate electrode 130, a source electrode 150, a gate connecting structure 140, a source electrode 150, a gate electrode 130, a drain electrode 180 are arranged in sequence. In other words, adjacent transistor cells share one first gate connecting section 1401, while each cell retains its own source electrode 150, gate electrode 130, and drain electrode 180. Thus, an impact of resistance of the gate electrode may be reduced, gain is improved and leakage current is reduced.

Optionally, further referring to FIG. 9, a dimension L of the source electrode 150 in the second direction X satisfies L≤60 μm, which is smaller than a dimension of a source electrode of a conventional semiconductor device. It can be understood as that the conventional source electrode is divided into two adjacent source electrode portions spaced apart of a certain distance to accommodate the first gate connecting section 1401, thereby reducing an area of the semiconductor device 10 and lowering costs.

In the above embodiments, in the thickness direction of the semiconductor device, the orthographic projection of the gate electrode 130 and the orthographic projection of the first gate connecting section 1401 do not overlap. In some embodiments, to further reduce an area of the semiconductor device, the orthographic projection of the first gate connecting section 1401 in the thickness direction of the semiconductor device may partially overlap with the orthographic projection of the gate electrode 130 in the thickness direction of the semiconductor device. More details are provided in the following embodiments.

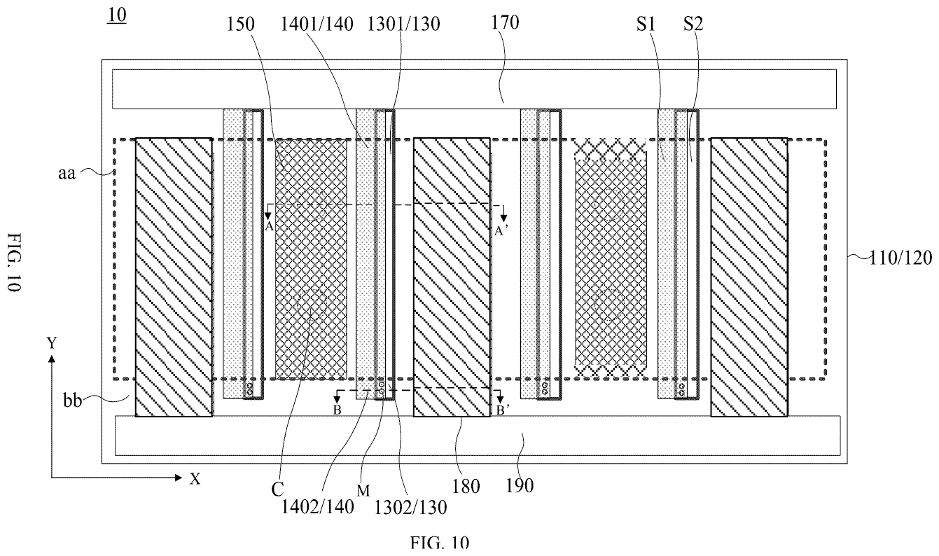

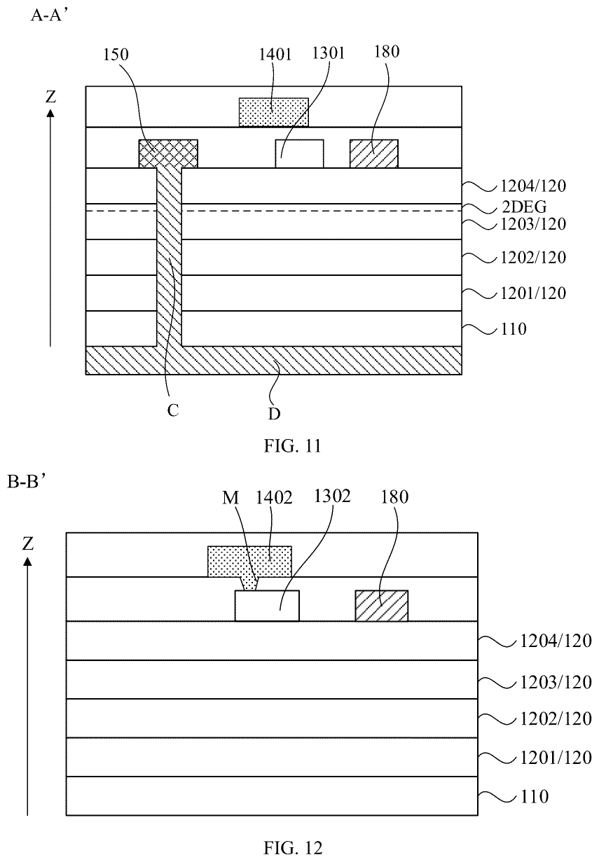

FIG. 10 is a schematic structural diagram of a semiconductor device provided by yet still another embodiment of the present disclosure. FIG. 11 is a cross-sectional view of the semiconductor device in FIG. 10 along section line A-A′. FIG. 12 is a cross-sectional view of the semiconductor device in FIG. 10 along section line B-B′. As shown in FIGS. 10 to 12, the semiconductor device 10 includes: an active region aa and a passive region bb surrounding the active region aa. The semiconductor device 10 further includes: a substrate 110; an epitaxial structure 120 located on a side of the substrate 110; a gate electrode 130 on a side, facing away from the substrate 110, of the epitaxial structure 120, where the gate electrode 130 extends in a first direction (i.e., a direction of Y as shown in FIG. 1), the first direction Y and a second direction X intersect and are parallel to the plane of the substrate 110, the gate electrode 130 includes a first gate section 1301 and a second gate section 1302 connected with each other, the first gate section 1301 forms a Schottky contact with the epitaxial structure 120, and the second gate section 1302 is located in the passive region bb; and at least one gate connecting structure 140, located on a side, facing away from the substrate 110, of the gate electrode 130, where the gate connecting structure 140 includes a first gate connecting section 1401 and a second gate connecting section 1402 connected with each other, the second gate connecting section 1402 is located in the passive region bb. In a thickness direction of the semiconductor device (a direction of Z as shown in FIG. 11), an orthographic projection of the first gate connecting section 1401 at least partially overlaps with an orthographic projection of the first gate section 1301, and an orthographic projection of the second gate connecting section 1402 at least partially overlaps with an orthographic projection of the second gate section 1302. The second gate connecting section 1402 is electrically connected to at least part of the second gate section 1302.

FIG. 10 illustrates a semiconductor device 10 with a plurality of gate electrodes 130. It should be understood that the device may also include only one gate electrode 130, forming a single-cell structure consisting of a source electrode 150, a gate electrode 130, and a drain electrode 180.

Specifically, the gate electrode 130 includes the first gate section 1301 and the second gate sections 1302 connected with each other. The first gate section 1301 forms a Schottky contact with the epitaxial structure 120, while the second gate section 1302 is located in the passive region bb, serving as a gate structure of the semiconductor device 10 to control a turning-on and turning-off state of the semiconductor device 10 and further an operating state of the semiconductor device 10. The first gate connecting section 1401, located in the active region aa with a relatively large area, as a main adjustment structure for the gain of the gate electrode 130, is configured to reduce resistance of the gate electrode 130 and improve a gain of the gate electrode 130. The second gate section 1302 and the second gate connecting section 1402, both located in the passive region bb, serve as connection portions between the gate electrode 130 and the gate connecting structure 140 to ensure a normal electrical connection between the gate electrode 130 and the gate connecting structure 140 and reduce the resistance of the gate electrode 130. Further, the second gate connecting section 1402 is electrically connected to at least part of the second gate section 1302, so that the resistance of the gate electrode 130 is reduced, thereby improving the gain and switching speed of the device. Additionally, in the thickness direction Z, the orthographic projection of the first gate connecting section 1401 partially overlaps with the orthographic projection of the first gate section 1301, and the orthographic projection of the second gate connecting section 1402 partially overlaps with the orthographic projection of the second gate section 1302. On one hand, it facilitates electrical connection between the second gate connecting section 1402 and the second gate section 1302; on the other hand, an area of the semiconductor device 10 may be reduced, which ensures a small structure of the semiconductor device 10, thereby enabling a more compact design of the device.

Optionally, further referring to FIGS. 10 and 12, at least part of the second gate section 1302 is electrically connected to the second gate connecting section 1402 through a connection via hole M. In the second direction X, a size of the connection via hole M is smaller than that of the second gate section 1302 and the second gate connecting section 1402. Specifically, at least part of the second gate section 1302 is electrically connected to the second gate connecting section 1402 through the connection via hole M in the passive region bb, which ensures that an arrangement of the semiconductor device 10 in the active region aa may not be affected, and will not affect a normal operation of the semiconductor device 10 in the active region aa, thereby ensuring stability of the performance of the semiconductor device 10. Moreover, since there is a large arrangement space in the passive area bb, there is a relatively large design flexibility for the second gate section 1302 and the second gate connecting section 1402, so that connection stability between the second gate section 1302 and the second gate connecting section 1402 may be improved. In the second direction X, the size of the connection via hole M is smaller than the size of the second gate section 1302 and the size of the second gate connecting section 1402, which can ensure that the second gate connecting section 1402 is fully electrically connected to the second gate section 1302, further reducing a resistance and leakage current of the gate electrode 130.

Optionally, further referring to FIGS. 10 and 11, the source electrode 150 can be connected to the backside of the semiconductor device 10 through a source via hole C. Exemplarily, the source via hole C may penetrate the substrate 110 and the epitaxial structure 120, that is, a source signal input electrode D on a side, facing away from the epitaxial structure 120, of the substrate 110 is connected to the source electrode 150 through the source via hole C. In other words, the source electrode 150 is electrically connected to the source signal input electrode D through the source via hole C. Further, the first gate connecting section 1401 may be positioned above the source via hole C to ensure stability of a region of the source via hole C, enabling normal operation of the semiconductor device 10.

Optionally, further referring to FIG. 10, the semiconductor device 10 may further include a gate pad 170. In the first direction Y, the gate pad 170 is located in the passive region bb at a first side of the active region aa. Both the first gate section 1301 and the first gate connecting section 1401 are electrically connected to the gate pad 170. The first gate connecting section 1401 may be arranged in a same layer as the gate pad 170. Exemplarily, in the first direction Y, the gate electrode 130 in the active region aa may be connected to the gate pad 170 in the passive region bb through gate interconnect metal, so that the gate electrode 130 may receive a gate voltage signal via the gate pad 170, thereby ensuring normal operation of the semiconductor device 10. Specifically, the first gate connecting section 1401 is arranged in a same layer as the gate pad 170. Thus, a preparation process may be simplified. On one hand, arrangement of unnecessary additional layers may be avoided to reduce masking complexity; on the other hand, it may facilitate a thinner and lighter design for the semiconductor device 10.

Optionally, further referring to FIG. 10, the semiconductor device 10 may include a drain electrode 180 and a drain pad 190 connected with each other. The drain electrode 180 forms an ohmic contact with the epitaxial structure 120. In the first direction Y, the drain pad 190 is located on a second side of the active region aa. In the first direction Y, the second gate connecting section 1402 is located on a side, closer to the drain pad 190, of the active region aa. Exemplarily, the drain electrode 180 in the active region aa may be connected to the drain pad 190 in the passive region bb through drain interconnect metal. Specifically, in the first direction Y, the drain pad 190 is located on the second side of the active region aa, that is, the drain electrode 180 may receive a drain voltage signal through the drain pad 190, thereby ensuring the normal operation of the semiconductor device 10.

Furthermore, in the first direction Y, the second gate connecting section 1402 is located between the active region aa and the drain pad 190, which reduces an area of the passive region bb, further reducing an area of the semiconductor device 10, thereby achieving miniaturized design for the device

Optionally, further referring to FIG. 11, the epitaxial structure 120 may include a nucleation layer 1201, a buffer layer 1202, a channel layer 1203, and a barrier layer 1204 stacked in sequence. A heterojunction structure is formed by the channel layer 1203 and the barrier layer 1204. More description of the epitaxial structure 120 may be referred to FIG. 1, which will not be repeated in this embodiment.

In view of above, according to the semiconductor device provided by the embodiments of the present disclosure, at least one gate connecting structure is provided in the semiconductor device. By electrically connecting the second gate connecting section to at least part of the second gate section, resistance of the gate electrode is reduced, thereby improving a gain of the gate electrode and improving switching speed of the device. Further, since the first gate connecting section overlaps with at least part of the first gate section, an area of the semiconductor device 10 may be reduced, which ensures a small structure of the semiconductor device 10, thereby enabling a more compact design of the device.

Optionally, in the thickness direction of the semiconductor device 10, an orthographic projection of the gate connecting structure 140 may cover an orthographic projection of the gate electrode 130. Exemplarily, the gate connecting structure 140 is located above the gate electrode 130, and the orthographic projection of the gate connecting structure 140 in the thickness direction of the semiconductor device 10 overlaps with the orthographic projection of the gate electrode 130 in the thickness direction of the semiconductor device 10. Thus, on one hand, it is beneficial for an electrical connection between the gate connecting structure 140 and the gate electrode 130 and improve connection stability of the electrical connection, thereby ensuring normal performance of the semiconductor device 10; on the other hand, a dimension of the active region aa in the second direction X may be reduced, thereby enabling a more compact design of the device.

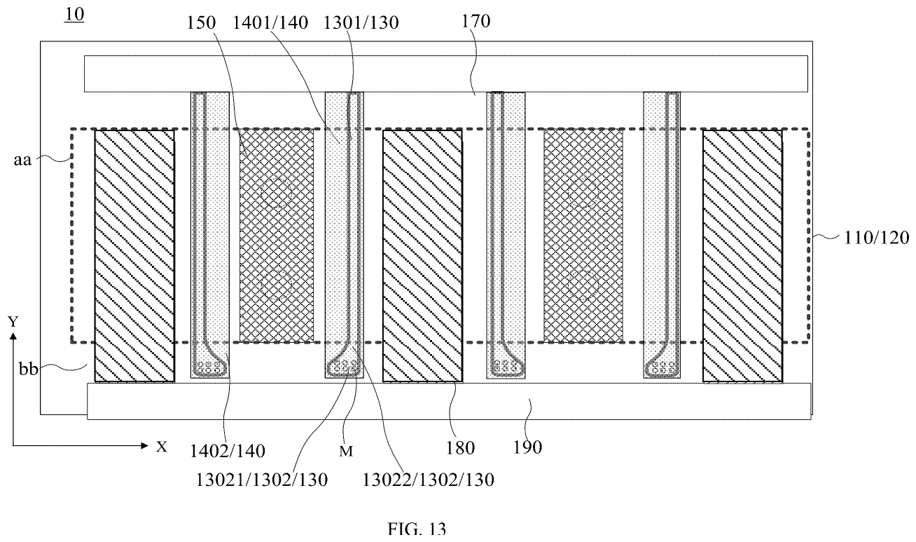

Optionally, FIG. 13 is a schematic diagram of the structure of a semiconductor device provided by yet still another embodiment of the present disclosure. As shown in FIG. 13, the second gate sub-portion 1302 includes a first sub-portion 13021 and a second sub-portion 13022. The first sub-portion 13021 is located on the side, farther away from the active region aa, of the second sub-portion 13022. In the second direction X, a dimension of the first sub-portion 13021 is larger than a dimension of the second sub-portion 13022. The second direction X and the first direction Y intersect and are parallel to the plane of the substrate 110. The second gate connection section 1402 is electrically connected to the first sub-portion 13021, that is, a connection position between the second gate connecting section 1402 and the second gate section 1302 is set in a wider part of the second gate section 1302. Thus, on one hand, stability of the connection may be improved, making the connection firmer and the structure more stable. On the other hand, a connection resistance and connection difficulty between the second gate connecting section 1402 and the second gate section 1302 may be reduced.

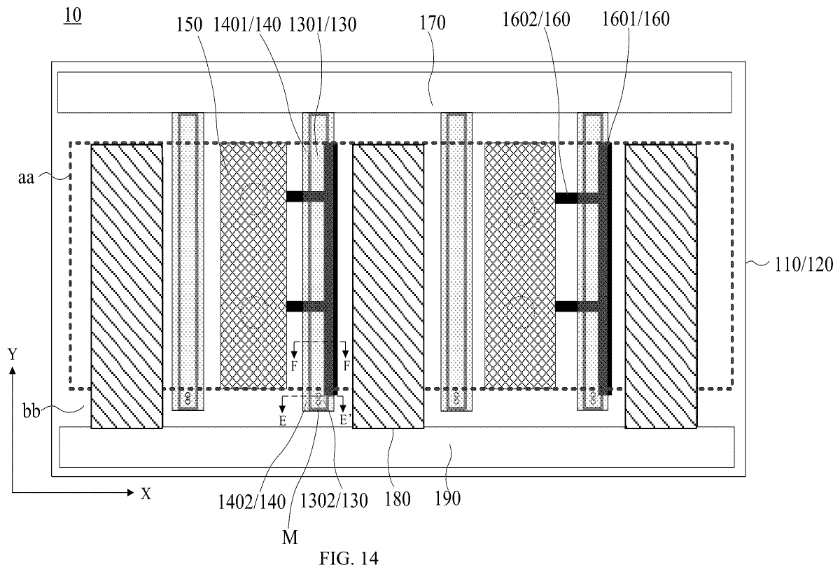

Optionally, FIG. 14 is a schematic diagram of the structure of a semiconductor device provided by yet still another embodiment of the present disclosure. As shown in FIG. 14, the semiconductor device 10 may further include a source electrode 150 and a source field plate 160. The source field plate 160 is located between a film layer where the gate electrode 130 is located and a film layer where the gate connecting structure 140 is located.

Exemplarily, further referring to FIG. 14, an orthographic projection of the field plate main body 1601 on the substrate 110 may overlap with a side, closer to the drain electrode 180, of an orthographic projection of the gate electrode 130 on the substrate 110. Thus, the source field plate 160 extends toward the gate electrode 130, further enhancing a modulation effect on the electric field of the source field plate 160. By reducing electric field accumulation of at drain-side edge of the gate electrode 130, a risk of breakdown at this edge of the gate electrode 130 is lowered, thereby improving the reliability of the semiconductor device 10. Exemplarily, the source field plate 160 includes a field plate main body 1601 and a field plate branch 1602. One end of the field plate branch 1602 is electrically connected to the field plate main body 1601, and the other end of the field plate branch 1602 is electrically connected to the source electrode 150, enabling an electrical connection between the source field plate 160 and the source electrode 150.

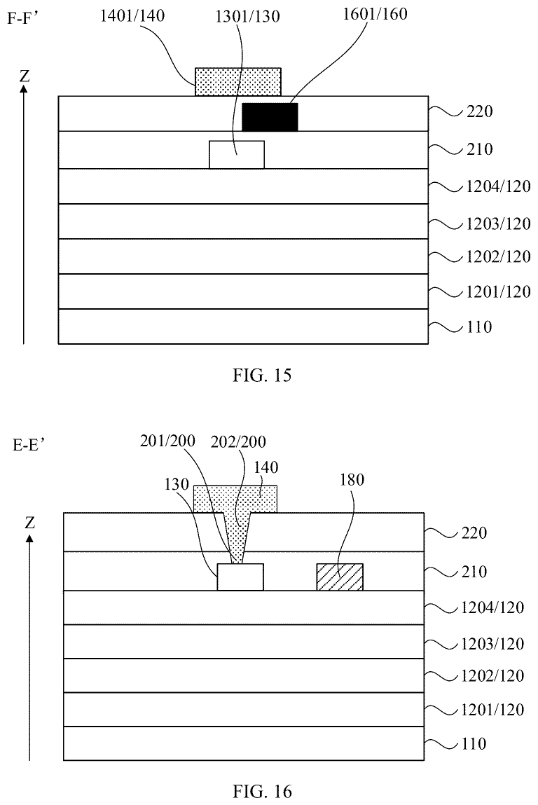

Furthermore, FIG. 15 is a cross-sectional view of the semiconductor device provided in FIG. 14 along section line F-F′. Further referring to FIGS. 14 and 15, the source field plate 160 is located between the film layer where the source electrode 150 is located and the film layer where the gate electrode 130 is located. In other words, the gate electrode 130, the source field plate 160, and the gate connecting structure 140 are arranged in different layers, to ensure a greater degree of freedom in the arrangement of different structures located in the active region aa and, on the other hand, to reduce mutual interference.

Optionally, further referring to FIG. 14, in the first direction Y, a dimension of the second gate section 1302 is greater than a dimension of the source field plate 160 in the passive region bb, and a dimension of the second gate connecting section 1402 is greater than the dimension of the source field plate 160 in the passive region bb. In other words, in the first direction Y, extension lengths of the second gate section 1302 and the second gate connecting section 1402 in the passive region bb is greater than an extension length of the source field plate 160 in the passive region bb, so that there is no influence of the source field plate 160 covering the gate electrode 130. The dimension and position of the source field plate 160 and the gate connecting structure 140 can be freely designed, thereby improving the stability of the connection between the gate connecting structure 140 and the gate electrode 130 and optimizing device performance.

Optionally, FIG. 16 is a cross-sectional view of the semiconductor device provided in FIG. 14 along section line E-E′. As shown in FIGS. 15 and 16, the semiconductor device 10 further includes a first dielectric layer 210 located between a film layer where the source field plate 160 is located and a film layer where the gate electrode 130 is located, and a second dielectric layer 220 located between the film layer where the source field plate 160 is located and a film layer where the gate connecting structure 140 is located. That is, the source field plate 160, the gate electrode 130, and the gate connecting structure 140 are located in different film layers, so that mutual interference may be avoided. In the thickness direction Z of the semiconductor device 10, an orthographic projection of the source field plate 160 overlaps with an orthographic projection of the first gate section 1301, where a thickness d1 of the first dielectric layer 210 satisfies d1≥300 nm; and/or, the orthographic projection of the source field plate 160 overlaps with an orthographic projection of the first gate connecting section 1401, where a thickness d2 of the second dielectric layer 220 satisfies d2≥300 nm. Thus, an area of the semiconductor device 10 may be reduced, thereby achieving device miniaturization. In addition, by increasing the thickness of the first dielectric layer 210 or the second dielectric layer 220 (e.g. d1≥300 nm, and/or, d2≥300 nm), parasitic capacitance between the source field plate 160 and the first gate section 1301 and/or the first gate connecting section 1401 may be reduced, thereby reducing the impact on the performance of the semiconductor device 10 and ensuring its normal operation.

FIG. 15 only shows a technical solution where the orthographic projection of the source field plate 160 in the thickness direction of the semiconductor device 10 overlaps with both the orthographic projection of the first gate section 1301 in the thickness direction of the semiconductor device 10 and the orthographic projection of the first gate connecting section 1401 in the thickness direction of the semiconductor device 10, which is described for illustrative purposes only and does not constitute a limitation to the present disclosure. In other embodiments, the orthographic projection of the source field plate 160 in the thickness direction of the semiconductor device 10 only overlaps with the orthographic projection of the first gate section 1301 in the thickness direction of the semiconductor device 10, or the orthographic projection of the source field plate 160 in the thickness direction of the semiconductor device 10 only overlaps with the orthographic projection of the first gate connecting section 1401 in the thickness direction of the semiconductor device 10.

Optionally, further referring to FIGS. 14 and 16, the gate connecting structure 140 is electrically connected to the gate electrode 130 through a connection pillar 200. The connecting pillar 200 includes a first connecting pillar section 201 located in the first dielectric layer 210 and a second connecting pillar section 202 located in the second dielectric layer 220. The first connection pillar section 201 and the second connection pillar section 202 are integrated and integrated with the gate connecting structure 140. Alternatively, the first connection pillar section 201 is integrated with the source field plate 160, and the second connection pillar section 202 is integrated with the gate connecting structure 140.

Specifically, the gate connecting structure 140 is electrically connected to the gate electrode 130 through the connection pillar 200 to improve connection stability, thereby reducing the resistance of the gate electrode 130. Furthermore, in the first dielectric layer 210, the first connection pillar section 201 of the connection pillar 200 is electrically connected to the gate electrode 130, and then the first connection pillar section 201 is electrically connected to the second connection pillar section 202 located in the second dielectric layer 220, thereby achieving the electrical connection between the gate connecting structure 140 and the gate electrode 130 through the connection pillar 200. As a feasible implementation, referring to FIG. 16, the first connection pillar section 201 and the second connection pillar section 202 are integrated and integrated with the gate connecting structure 140, so that a preparation process of the semiconductor device 10 may be simplified, thereby improving the reliability of the preparation process. As another feasible implementation, the first connection pillar section 201 is integrated with the source field plate 160, and the second connection pillar section 202 is integrated with the gate connecting structure 140. Specifically, before forming the source field plate 160, the first dielectric layer 210 is etched above the gate electrode 130 to form an opening exposing the gate electrode 130. In the process of forming the source field plate 160, an electrical connection is formed between the first connection pillar section 201 and the gate electrode 130 at the opening of the first dielectric layer 210. Then, the second dielectric layer 220 is deposited, and an opening is further formed above the gate electrode 130 in the second dielectric layer 220. The second connection pillar section 202 is filled above and in the opening of the second dielectric layer 220 to form the gate connecting structure 140. The connection pillar 200 here is not integrally formed, but is formed by a two-step process, that is, the first connection pillar section 201 is integrated with the source field plate 160, and the second connection pillar section 202 is integrated with the gate connecting structure 140.

It should be understood that in the embodiments of the present disclosure, from a perspective of semiconductor device design, the gate connecting structure is provided to reduce an impact of resistance of the gate electrode, so that switching speed and gain is improved, thereby improving the reliability of semiconductor device. The semiconductor devices described above includes but are not limited to: high-power high electron mobility transistors (HEMTs) operating in high voltage and high current environments, silicon on insulator (SOI) structure transistors, gallium arsenide (GaAs)-based transistors, metal oxide semiconductor field effect transistors (MOSFETs), metal insulating layer semiconductor field effect transistors (MISFETs), double heterojunction field effect transistors (DHFETs), Junction Field Effect Transistor (JFET), Metal Semiconductor Field Effect Transistor (MESFET), Metal Insulator Heterojunction Field Effect Transistor (MISHFET), or other field-effect transistors. The gate connecting structure provided in the embodiments of the present invention may be widely used in the manufacturing fields of semiconductor devices such as radio frequency microwave and power electronics. Especially for gallium nitride electronic devices with large band gap, high electron mobility, high breakdown field strength, and good thermal conductivity, the advantages are more obvious, which can better meet the high-performance requirements of rapidly developing fields such as electronic communication.

It should be noted that the above are only preferred embodiments and technical principles applied in the present disclosure. Those skilled in the art will understand that the present disclosure is not limited to the specific embodiments described herein, and various obvious changes, readjustments, and substitutions can be made for those skilled in the art without departing from the scope of protection of the present disclosure. Therefore, although the present disclosure has been described in detail through the above embodiments, the present disclosure is not limited to the above embodiments, and may also include more equivalent embodiments without departing from the concept of the present disclosure. The scope of the present disclosure is determined by the scope of the appended claims.

What is claimed is:

1. A semiconductor device, comprising:
a substrate;
an epitaxial structure located on a side of the substrate;
a gate electrode located on a side, facing away from the substrate, of the epitaxial structure, wherein the gate electrode extends in a first direction parallel to a plane of the substrate, the gate electrode comprises a first gate section and a second gate section connected with each other and the gate electrode is in Schottky contact with the epitaxial structure; and
a gate connecting structure comprising a first gate connecting section and a second gate connecting section connected with each other, wherein the second gate connection section is electrically connected to at least part of the gate electrode.

2. The semiconductor device according to claim 1, further comprising:
an active region and a passive region surrounding the active region, wherein the second gate connecting section is located in the active region, the first gate section is located in the active region, and the second gate connecting section is electrically connected to at least part of the first gate section.

3. The semiconductor device according to claim 2, wherein a minimum distance between the second gate connecting section and an edge of the active region is L1, wherein L1≤5 μm.

4. The semiconductor device according to claim 1, further comprising:
an active region and a passive region surrounding the active region, wherein the second gate connecting section is located in the passive region, and the second gate section is located in the passive region; and the second gate connecting section is electrically connected to at least part of the second gate section.

5. The semiconductor device according to claim 1, wherein an orthographic projection of the first gate connecting section on the substrate at least partially overlaps with an orthographic projection of the first gate section on the substrate, and an orthographic projection of the second gate connecting section on the substrate at least partially overlaps with an orthographic projection of the second gate section on the substrate.

6. The semiconductor device according to claim 1, wherein an orthographic projection of the gate connecting structure in a thickness direction of the semiconductor device covers an orthographic projection of the gate electrode in the thickness direction of the semiconductor device.

7. The semiconductor device according to claim 1, wherein an orthographic projection of the first gate section in a thickness direction of the semiconductor device does not overlap with an orthographic projection of the first gate connecting section in the thickness direction of the semiconductor device.

8. The semiconductor device according to claim 7, further comprising a source electrode in an ohmic contact with the epitaxial structure; wherein the orthographic projection of the first gate connecting section in the thickness direction of the semiconductor device overlaps with an orthographic projection of the source electrode in the thickness direction of the semiconductor device, and the first gate connecting section is insulated from the source electrode.

9. The semiconductor device according to claim 8, a dimension of the first gate connecting section in a second direction is less than a dimension of the source electrode in the second direction, and the second direction and the first direction intersect and are parallel to the plane of the substrate.

10. The semiconductor device according to claim 7, further comprising a source electrode in an ohmic contact with the epitaxial structure; wherein the first gate connecting section is located on a side, farther away from the gate electrode in a second direction, of the source electrode and between two adjacent source electrodes, and the second direction and the first direction intersect and are parallel to the plane of the substrate.

11. The semiconductor device according to claim 1, wherein the gate connecting structure further comprises a third gate connecting section located in an active region and electrically connected to the first gate connecting section and the first gate section respectively.

12. The semiconductor device according to claim 11, further comprising: a source electrode and a source field plate; wherein
the source field plate comprises a field plate main body and a field plate branch, the field plate branches are electrically connected to the field plate main body and the source electrode respectively; and
an orthographic projection of the field plate branch in a thickness direction of the semiconductor device is arranged offset from an orthographic projection of the third gate connecting section in the thickness direction of the semiconductor device.

13. The semiconductor device according to claim 12, wherein an orthographic projection of the source field plate in the thickness direction of the semiconductor device is staggered with an orthographic projection of the gate electrode in the thickness direction of the semiconductor device.

14. The semiconductor device according to claim 12, wherein an orthographic projection of the source field plate in the thickness direction of the semiconductor device covers an edge, farther away from the source electrode of an orthographic projection of the gate electrode in the thickness direction of the semiconductor device, an overlap area between the source field plate and the gate electrode is S1, an area of the gate electrode is S2, and a ratio of S1 to S2 is less than or equal to 20%.

15. The semiconductor device according to claim 1, further comprising an active region and a passive region surrounding the active region; and
a gate pad located in the passive region on a first side of the active region along the first direction; wherein
the first gate section and the first gate connecting section are electrically connected to the gate pad.

16. The semiconductor device according to claim 15, further comprising:
a source electrode and a source field plate electrically connected to the source electrode; wherein
the first gate connecting section is arranged in a same layer as the gate electrode; or
the first gate connecting section is arranged in a same layer as the source field plate; or
the first gate connecting section is arranged in a same layer as the gate pad; or
the source field plate is located between a layer of the gate electrode and a layer of the gate electrode connecting structure.

17. The semiconductor device according to claim 16, further comprising:
a first dielectric layer between a layer of the source field plate and the layer of the gate electrode, and
a second dielectric layer between the layer of the source field plate and the layer of the gate connecting structure; wherein
an orthographic projection of the source field plate in a thickness direction of the semiconductor device overlaps with an orthographic projection of the first gate section in the thickness direction of the semiconductor device, and a thickness d1 of the first dielectric layer satisfies d1≥300 nm; and/or
the orthographic projection of the source field plate in the thickness direction of the semiconductor device overlaps with an orthographic projection of the first gate connecting section in the thickness direction of the semiconductor device, and a thickness d2 of the second dielectric layer satisfies d2≥300 nm.

18. The semiconductor device according to claim 1, wherein a dimension of the first gate connecting section in a second direction is greater than a dimension of the first gate section in the second direction, and the second direction and the first direction intersect and are parallel to the plane of the substrate.

19. The semiconductor device according to claim 1, wherein
the gate connecting structure is electrically connected to the gate electrode located on a side, in a second direction, of the first gate connecting section through the second gate connecting section; or
the semiconductor device comprises a plurality of gate electrodes arranged in sequence in a second direction, and the gate connecting structure is electrically connected to two gate electrodes located on both sides, in the second direction, of the first gate connecting section through the second gate connecting section.

20. The semiconductor device according to claim 1, wherein an angle α between the second gate connecting section and the first gate connecting section satisfies 80°≤α≤100°.
